(19) United States
(12) Patent Application Publication
(10) Pub. No.: US 2023/0253217 A1
(43) Pub. Date: Aug. 10, 2023

(54) SUBSTRATE TRANSFER DOOR ASSEMBLIES WITH RADIATING ELEMENTS FOR SUBSTRATE PROCESSING CHAMBERS

(71) Applicant: LAM RESEARCH CORPORATION, Fremont, CA (US)

(72) Inventors: John DREWERY, San Jose, CA (US); David INORI, Livermore, CA (US); Andre DESEPTE, San Jose, CA (US); Michael Julius KINSLER, Oakland, CA (US)

(21) Appl. No.: 18/013,161

(22) PCT Filed: Aug. 23, 2021
(86) PCT No.: PCT/US2021/047054

§ 371 Date: Dec. 27, 2022

Related U.S. Application Data
(60) Provisional application No. 63/072,128, filed on Aug. 29, 2020.

(51) Int. Cl. H01L 21/67; H01L 21/673

(52) U.S. Cl. CPC H01L 21/67115; H01L 21/6719; H01L 21/67196; H01L 21/67346

(57) ABSTRACT

A substrate transfer door assembly includes a body, one or more radiating elements, a member, and at least one lifting coupler. The body includes a central portion. At least the central portion of the body operates as a substrate transfer door and covers at least one of an opening of a liner or an opening of a chamber wall of a substrate processing chamber. The one or more radiating elements radiating heat away from the body. The member extends from the body. The at least one lifting coupler is connected to the member and movable in a vertical direction between an open position and a closed position to cover the at least one of the opening of the liner or the opening of the chamber wall with the central portion of the body.

### CROSS-REFERENCE TO RELATED APPLICATIONS

This application claims the benefit of U.S. Provisional App. No. 63/072,128, filed on Aug. 29, 2020. The entire disclosure of the application referenced above is incorporated herein by reference.

### FIELD

The present disclosure relates to substrate processing chambers, and more particularly to doors for transferring substrates to and from a substrate processing chamber.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures including one or more precursors may be introduced into the processing chamber and plasma may be used to initiate chemical reactions.

The substrate may be transferred to and from the processing chamber through a substrate transfer door of the processing chamber via a robot. The substrate transfer door can receive a significant amount of heat during substrate processing. This may occur due to plasma impingement, electrical heating (e.g., heating due to radio frequency (RF) heating), and surface chemical reactions.

### SUMMARY

A substrate transfer door assembly is provided and includes a body, one or more radiating elements, a member, and at least one lifting coupler. The body includes a central portion. At least the central portion of the body operates as a substrate transfer door and covers at least one of an opening of a liner or an opening of a chamber wall of a substrate processing chamber. The one or more radiating elements radiating heat away from the body. The member extends from the body. The at least one lifting coupler is connected to the member and movable in a vertical direction between an open position and a closed position to cover the at least one of the opening of the liner or the opening of the chamber wall with the central portion of the body.

In other features, the one or more radiating elements include a bottom extension member that extends down from the body. In other features, the one or more radiating elements include side extension members extending in an azimuthal direction away from the body.

In other features, the one or more radiating elements include a fin extending radially from the body. In other features, the substrate transfer door assembly further includes one or more support members extending from and supporting the fin.

In other features, the substrate transfer door assembly further includes: a frame connected to and extending radially from the body; and a web held by the frame. The frame includes the member. The one or more radiating elements include the web.

In other features, the member is a first member. The frame includes multiple members including the first member. The web extends between and is connected to each of the members. In other features, the one or more radiating elements extend radially away from the body and toward the member.

In other features, the one or more radiating elements include radiating elements extending radially away from the body. In other features, the substrate transfer door assembly further includes at least one support member extending radially from and structurally supporting the body.

In other features, the at least one support member counterbalances weight of at least a portion of the one or more radiating elements. In other features, the substrate transfer door assembly further includes support members connected to the body and to the lifting coupler. In other features, the support members at least one of radiate heat away from the body or counterbalance weight of at least a portion of the one or more radiating elements. In other features, the body covers the opening of the liner and the opening of the chamber wall.

In other features, the substrate transfer door assembly further includes a protective coating on at least a portion of an inner side of the body. A portion of the coating faces the at least one of the opening in the liner or the opening in the chamber wall. In other features, the protective coating faces at least one of an interior of the substrate processing chamber or the opening in the liner.

In other features, the body includes aluminum. The protective coating includes at least one of yttrium oxide, aluminum oxide, aluminum hydroxide, yttrium oxyfluoride, zirconium oxide, or yttrium trifluoride.

In other features, a substrate transfer system is provided and includes: the substrate transfer door assembly; an actuating element; an actuator connected to the actuating element; and a controller controlling the actuator to move the substrate transfer door assembly between an open state and a closed state.

In other features, the substrate transfer system further includes support members connected to the body and to the lifting coupler. The lifting coupler is connected to the actuating element.

In other features, the member extends from the body in a direction away from an interior of the substrate processing chamber. In other features, the one or more radiating elements extend into the opening of the substrate processing chamber. In other features, the central portion of the body is disposed between the liner and the chamber wall when the substrate transfer door assembly is in the closed state.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example of a substrate transfer system including a substrate transfer door illustrated in a closed state in accordance with the present disclosure;

FIG. 1B is a functional block diagram of the substrate transfer system of FIG. 1A with the substrate transfer door illustrated in an open state in accordance with the present disclosure;

FIG. 2 is a perspective view of an example of a liner and a substrate transfer door assembly in accordance with the present disclosure;

FIG. 3 is a perspective view of an example of a substrate transfer door assembly including a rearward extending fin, radiating extension members, and counterbalance support members in accordance with the present disclosure;

FIG. 4 is a perspective view of an example of a substrate transfer door assembly including a framed web in accordance with the present disclosure;

FIG. 5 is a perspective view of an example of another substrate transfer door assembly including a fin with dual purpose support members in accordance with the present disclosure;

FIG. 6 is a perspective view of an example of another substrate transfer door assembly including rearward extending radiating elements in accordance with the present disclosure;

FIG. 7 is a perspective view of an example of another substrate transfer door assembly including framed radiating elements in accordance with the present disclosure; and

FIG. 8 is a perspective view of an example of a substrate transfer door assembly with a framed perforated web in accordance with the present disclosure.

In the drawings, reference numbers may be reused to identify similar and/or identical elements.

### DETAILED DESCRIPTION

A substrate transfer door is a movable part that is actuated between open and closed states. The substrate transfer door is also disposed in an enclosed and confined area. In other words, there is limited space available for the substrate transfer door and associated components. For at least these reasons, it can be difficult to cool the substrate transfer door by conduction. If used, conductive cooling can also be ineffective. As a result, temperatures of the substrate transfer door can increase to a temperature where damage to the substrate transfer door occurs.

As an example, a liner door for a conductor etch processing chamber can experience temperatures where degradation begins to occur. The liner door closes off a transfer slot in a chamber liner of the processing chamber. When the temperature of the liner door exceeds 140° C., a surface coating on the liner door is damaged, which may cause particle formation and metal contamination. The liner door can be exposed to contents, such as reaction gases and/or plasma, located within the processing chamber and as a result increase in temperature to a point of degradation. Increasing processing power further increases temperatures, which increases the probability of processing chamber door degradation.

The examples set forth herein include substrate chamber door assemblies including radiating elements that extend from substrate transfer doors. The radiating elements increase total radiating surface areas associated with the substrate transfer doors and radiate heat away from the substrate chamber doors, which cools the substrate chamber doors. Radiation from the radiating elements decreases temperatures of the substrate chamber doors to temperatures below a threshold at which degradation can occur. The radiating elements extend outward from the substrate chamber doors toward cooler surfaces and/or components of the corresponding processing chambers for increased cooling. The radiating elements radiate thermal energy towards the cooler surfaces and/or components, which decreases temperatures of the substrate chamber doors. The radiating elements are effective in decreasing temperatures of the substrate chamber doors. The effectiveness increases rapidly when surface temperatures exceed 120° C.

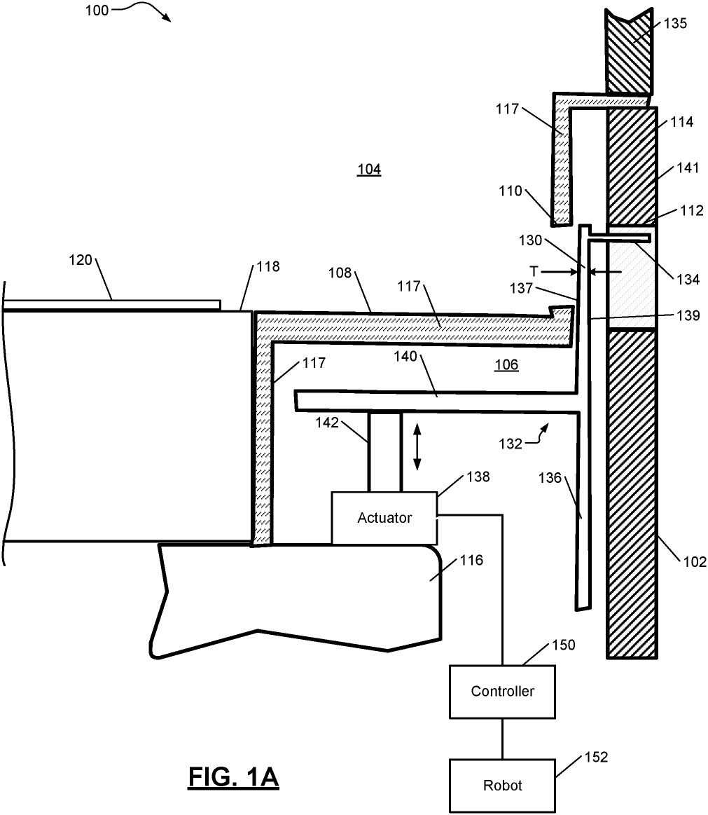

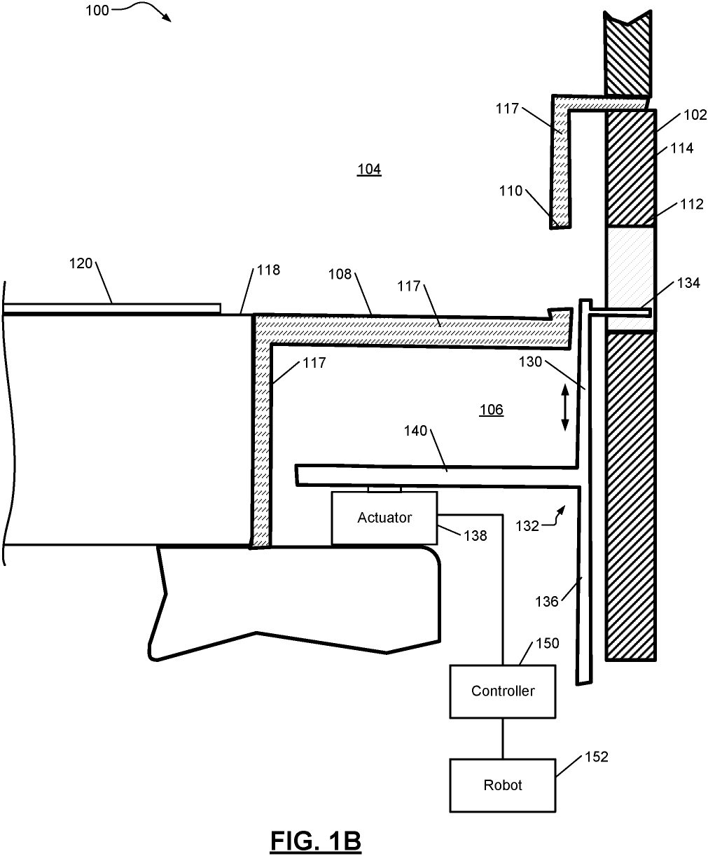

FIGS. 1A and 1B show a substrate transfer system 100 for a processing chamber 102 including an upper chamber region 104 and a lower chamber region 106. A cross-sectional portion of the processing chamber 102 is shown. The upper chamber region 104 is separated from the lower chamber region 106 by a liner 108 having an opening 110 that is in horizontal alignment with an opening 112 in a chamber wall 114. The opening 112 serves as a substrate transfer slot. The liner 108 extends from the chamber wall 114 to a cathode bowl (or bias housing) 116 and may include multiple members 117. Only a cross-sectional portion of the chamber wall 114 is shown. Substrates are transferred from outside the processing chamber 102 to a substrate support 118 (e.g., an electrostatic chuck) located within the processing chamber 102 though the openings 110, 112. A substrate 120 is shown on the substrate support 118. The substrate support 118 may be at least partially disposed on the cathode bowl 116, as shown.

The opening 112 of the processing chamber 102 is closed off by a substrate transfer door 130, which is part of a substrate transfer door assembly 132. The substrate transfer door 130 may be referred to as a conductor etch (CE) liner door when the substrate transfer door 130 is used to cover an opening of a liner of a CE processing chamber. FIG. 1A shows the substrate transfer door 130 in a closed state. FIG. 1B shows the substrate transfer door 130 in an open state. The substrate transfer door assembly 132 is attached to and may be integrally formed with radiating elements, such as a fin 134 and an extension member 136. The fin 134 extends in a radial direction rearward and into the opening 112. This allows the fin to radiate heat to the chamber wall 114, which may be at a cooler temperature than the liner 108 and/or the substrate transfer door 130.

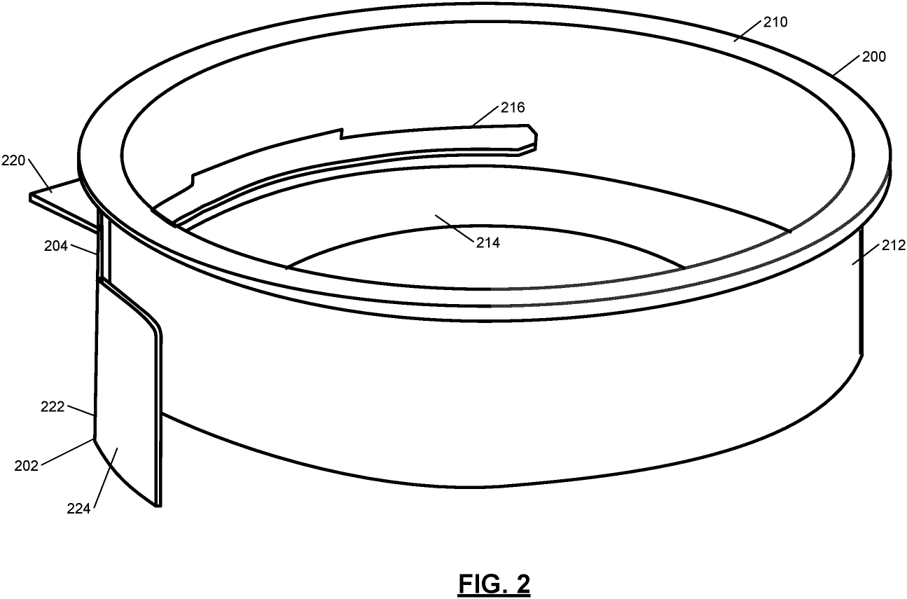

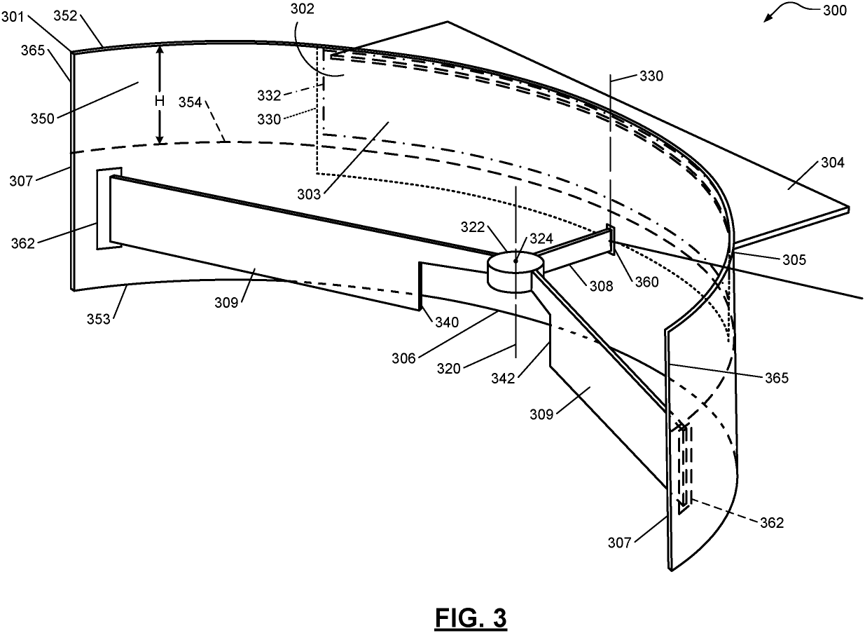

The extension member 136 extends downward from the substrate transfer door 130 and may extend in an azimuthal direction relative to a central portion of the substrate transfer door 130. The central portion may be a portion of the substrate transfer door 130 that covers the openings 110, 112 when the substrate transfer door 130 is in a closed state. The substrate transfer door 130 has an inner side 137 facing the liner 108 (referred to as the front side) and an outer side 139 facing the chamber wall 114 (referred to as the back side). As an example, the material of the chamber wall 114 may be at 70° C. and absorb heat from the fin 134, such that the substrate transfer door 130 is maintained at a temperature less than 140° C. As another example, an upper portion 135 of the chamber wall 114 may be at temperatures between 90-240° C., a lower portion 141 of the chamber wall 114 may be at temperatures between 60-70° C., and the fin 134 may be at temperatures between 100-150° C. Additional example extension members are shown in FIGS. 2-3.

The radiating elements increase surface area of the substrate transfer door 130 for increased cooling of the substrate transfer door 130. This is accomplished without increasing a size of the substrate transfer slot. The substrate transfer door 130 may have uniform or varying thickness. The thickness(es) of the substrate transfer door 130 (one thickness T is shown) are set to allow sufficient heat transfer from the substrate transfer door 130 to the radiating elements 134, 136 and/or other radiating elements. The substrate transfer door assembly 132 may have any of the radiating elements disclosed herein.

The radiating elements 134, 136 are provided as examples. The substrate transfer door assembly 132 may include additional, different and/or other radiating elements, some examples of which are disclosed below and in FIGS. 2-8. The substrate transfer door assembly 132 may include any number of radiating elements of various types, styles, shapes, sizes, weights, etc. The radiating elements may be configured in various layout patterns.

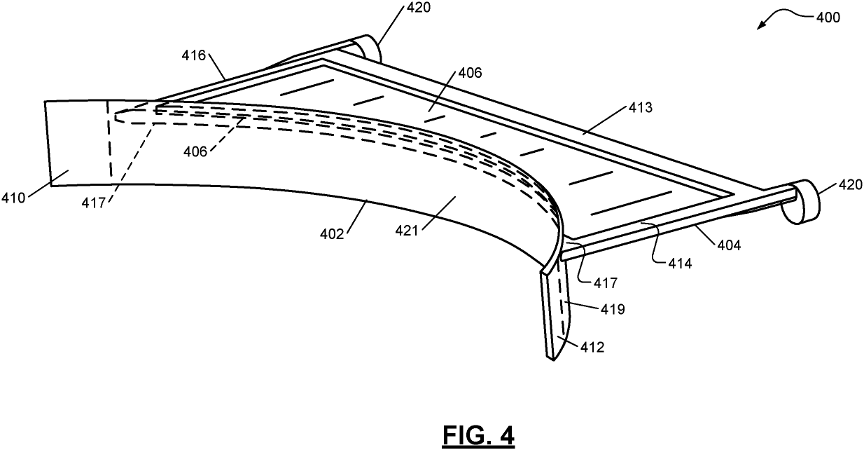

The substrate transfer door 130 is attached to an actuator 138 via one or more support members 140 and one or more actuating elements (one actuating element 142 is shown). Examples of the support members 140 are shown in FIGS. 3, 5 and 6. Substrate transfer doors similar to the substrate transfer door 130 are shown in FIGS. 3, 5 and 6. The substrate transfer doors in FIGS. 3, 5 and 6 correspond to substrate transfer doors disposed and actuated within a processing chamber. Other example substrate transfer doors are shown in FIGS. 4, 7 and 8. The substrate transfer doors of FIGS. 4, 7 and 8 correspond to substrate transfer doors disposed and actuated outside a processing chamber.

The actuator 138 may be a motor or a hydraulic, electric, and/or pneumatic actuator that actuates one or more of the actuating elements. The actuating elements may include: a screw that is rotated by the motor; a shaft that is actuated by the hydraulic, electric, and/or pneumatic actuator; linkages, gears; couplers; and/or other actuated elements. A controller 150 controls operation of the actuator 138 to control the position of the substrate transfer door 130 relative to the openings 110, 112. The substrate transfer door 130 is moved between the liner 108 and the chamber wall 114. When in a closed state, the substrate transfer door 130 blocks the openings 110, 112. In the example shown, the controller 150 moves the substrate transfer door 130 in a vertical (or z-axis) direction between a fully closed state and a fully open state. The controller 150 may also control a robot 152 that may transfer substrates to and from the processing chamber through the openings 110, 112. Although shown to the left of the chamber wall 114 and at the bottom of FIG. 1, the controller 150 and robot 152 are located outside the processing chamber.

FIG. 2 shows a liner 200 and a substrate transfer door assembly 202. The liner 200 is similar to the liner 108 of FIG. 1. The liner 200 may be cylindrically-shaped with an upper annular ledge 210, a cylindrically-shaped body 212 and a conically-shaped lower member 214. The body 212 includes an opening 216 for transferring substrates therethrough. The substrate transfer door assembly 202 includes a substrate transfer door 204 and radiating elements, such as a fin 220, a bottom extension member 222, and side extension members (one side extension member 224 is shown). The fin 220 extends rearward relative to the substrate transfer door 204. In one embodiment, the fin 220 extends horizontally and may be arranged perpendicular to at least a portion of the body 212. The substrate transfer door 204 covers the opening 216 when the substrate transfer door assembly 202 is in a fully closed state.

The bottom extension member 222 extends vertically downward from the substrate transfer door 204. The side extension members extend in an azimuthal direction from sides of the substrate transfer door 204 and the bottom extension member 222. The extension members 222, 224 may be integrally formed as part of the substrate transfer door 204. The fin 220 and the extension members 222, 224 increase surface area of the substrate transfer door and thus heat radiating surface area for increased cooling.

FIG. 3 shows a substrate transfer door assembly 300 including a body 301 having central portion 302 (operating as a substrate transfer door), and radiating elements. The radiating elements include: a rearward extending fin 304; extension members (a bottom extension member 306 and side extension members 307 are shown); and counterbalance support members (one center support member 308 and two angular support members 309 are shown). The central portion 302 has a front side 303 that faces the inside of a processing chamber and a back side 305 that faces away from the inside of the processing chamber. The counterbalance support members 308, 309 may provide a limited amount of radiative heat transfer.

The counterbalance support members 308, 309 provide structural support for the body 301. The counterbalance support members 308, 309 counterbalance weight of the fin 304 and/or other radiating elements, such that a center of gravity of the substrate transfer door assembly 300 is located along a centerline 320 of a central coupler 322. The counterbalance support members 308, 309 are connected to the central coupler 322. The center of gravity may be located at a center 324 of the central coupler 322. In one embodiment, the center of gravity is arranged within 0.5 millimeters (mm) of the center of the central coupler 322. The center of the central coupler 322 is along the centerline 320 of the central coupler 322. For example, the center support member 308 extends from a centerline 320 of the central portion 302, is perpendicular to the central portion 302, and aligns with the center 324 of the central coupler 322. The central coupler 322 may be configured (e.g., sized, shaped, and/or having connecting features, such as holes, tabs, etc.) to connect to the actuating element 142 of FIG. 1.

The central (or main) portion 302 of the body 301 is represented by dashed area 330), which covers an opening of a liner and/or an opening of a processing chamber. The portion of the substrate transfer door that covers and is in alignment with the opening of the liner and the opening of the processing chamber is represented by area 332. The area 330 may extend outward past the area 332 by predetermined amounts as shown, such that the central portion 302 overlaps portions of a corresponding liner and/or chamber wall. The central portion 302 may be referred to as a baseline portion that satisfies requirements for covering the opening of the liner and/or the opening of the chamber wall. Portions of the body 301 that extend from the central portion 302 may be referred to as radiating portions or radiating extension members (e.g., the extension members 306, 307).

The extension members 306, 307 extend from the central portion 302. The fin 304 and the extension members 306, 307 substantially increase radiative surface area of the central portion 302. As an example, the fin 304 and the extension members 306, 307 may increase the amount of surface area by 400-600%. As another example, fin 304 and the extension members 306, 307 may increase the amount of surface area by 343,000 mm²-445,000 mm².

The support members 308, 309 may have various sizes and shapes. The support members 308, 309 may be linearly shaped as shown or may have curved portions. The support members 308, 309 may be rectangularly-shaped, have notches (e.g., notches 340, 342), and/or have other supporting and/or radiating features.

An upper inner portion of the body 301 may have a protective coating 350. The body 301 includes cores of the central portion 302 and the extension members 306, 307. The body and corresponding top and bottom edges 352, 353 may be semi-circular shaped as shown. Although the protective coating 350 is shown extending to side edges 365 of the substrate transfer door assembly 300, the protective coating 350 may simply cover one of the areas 330 or 332. In another embodiment, the protective coating 350 has the height H as shown, but extends to the side edges 365 of one of the areas 330, 332. The height H extends from a top edge 352 of the substrate transfer door assembly 300 to a semi-circular line 354 located (i) below the opening of the processing chamber, and (ii) above the support members 308, 309 and corresponding support member mounts 360, 362. The support member mounts 360, 362 may be in various sizes and shapes and used to connect the support members 308, 309 to the body 301.

The body 301, the fin 304, the support members 308, 309, and the support member mounts 360, 362 may be formed of aluminum. In one embodiment, the body 301, the fin 304, the support members 308, 309, and/or the support member mounts 360, 362 are formed of anodized aluminum, such as black anodized aluminum for high emissivity. The protective coating 350 may be formed of yttrium oxide, aluminum oxide, aluminum hydroxide, yttrium oxyfluoride, zirconium oxide, and/or yttrium trifluoride. The protective coating 350 protects the aluminum body in areas where the substrate transfer door comes in contact with plasma and/or processing gases. The protective coating 350 protects the body 301 in at least areas that may be exposed to plasma and/or processing gases. For ease of manufacturing, the protective coating 350 is shown as extending between the side edges 365. The disclosed radiating elements aid in reducing temperatures of the anodized aluminum to prevent cracking and/or corrosion of the body 301. This increases lifetime of the substrate transfer door assembly 300 and prevents metal contamination within the processing chamber 102.

FIG. 4 shows a substrate transfer door assembly 400 that includes a central portion 402, a frame 404 and a web 406. The central portion 402 operates as a substrate transfer door. Side extension members 410, 412 extend from and may be integrally formed with the central portion 402 to provide a unitary structure. The frame 404 includes a first lateral member 413 and side members 414, 416, which are attached to a back side 419 of the central portion 402. The unitary structure has a back side 419 that faces away from a processing chamber and a front side 421 that faces the processing chamber. The frame 404 may include a second lateral member 417 that extends along the back side 419 of the central portion 402. The side members 414, 416 extend radially from the central portion 402 (or the second lateral member 417 if included) to the first lateral member 413. The central portion 402 (and/or the second lateral member 417 if included) and the members 413, 414, 416 are connected to and extend along a perimeter of the web 406. The web 406 increases surface area of the substrate transfer door assembly 400 to cool the central portion 402. The side members 414, 416 are connected to round bosses (or lifting couplers) 420, which may be connected to an actuator (similar to the actuator 138 of FIG. 1) that moves the substrate transfer door assembly 400 in a vertical and/or horizontal direction to cover and uncover an opening of a processing chamber. In one embodiment, the actuator includes one or more valves and the lifting couplers 420 are connected directly or indirectly to the one or more valves. The substrate transfer door assembly 400 may be moved horizontally away from a corresponding liner prior to being moved vertically to an open state. The substrate transfer door assembly 400 may then be moved vertically and then horizontally toward the liner to a closed state. By moving the liner door away from the liner, sliding contact with the liner is prevented while moving vertically. The substrate transfer door assembly 400 may also or alternatively be moved to seal off an opening of a vacuum transfer module when moved in a horizontal direction.

The central portion 402, frame 404, web 406, extension members 410, 412, and lifting couplers 420 may be formed of aluminum. In one embodiment, the substrate transfer door 402, frame 404, web 406, extension members 410, 412, and/or lifting couplers 420 are formed of anodized aluminum, such as black anodized aluminum. A protective coating may be applied to the front side 421 of the substrate transfer door. The protective coating may be formed of yttrium oxide, aluminum oxide, aluminum hydroxide, yttrium oxyfluoride, zirconium oxide, and/or yttrium trifluoride.

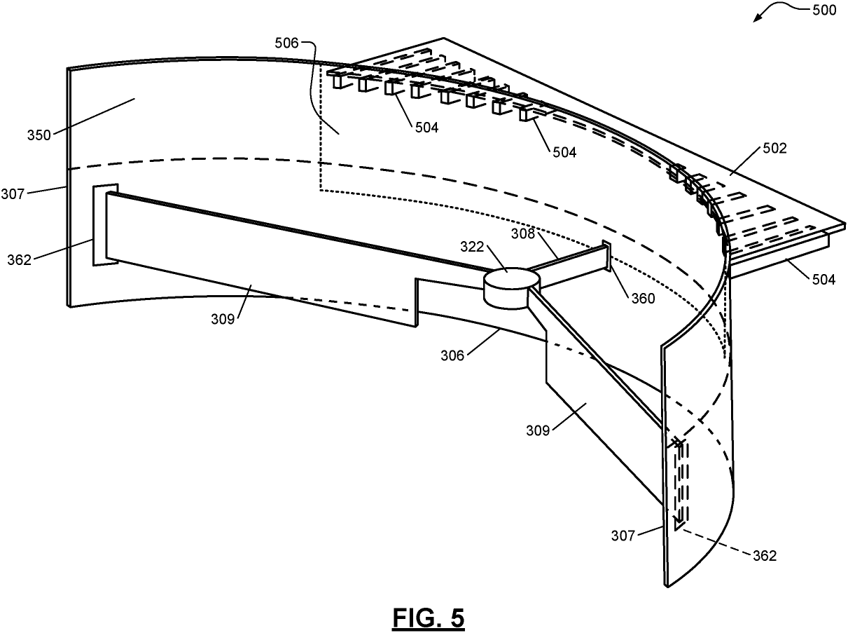

FIG. 5 shows another substrate transfer door assembly 500 that is similar to the substrate transfer door assembly 300 of FIG. 3, but includes a fin 502 with support members 504. The support members 504 may extend perpendicular to the fin 502 and from a front side of a substrate transfer door 506. The support members 504 may be rectangularly-shaped or be shaped differently than shown. The support members 504 provide structural support for the fin 502 and increase surface area for radiating heat. The fin 502 and the support members 504 may be referred to as radiating elements. The substrate transfer door 506 includes the extension members 306, 307. The substrate transfer door assembly 500 includes the support members 308, 309, central coupler 322 and support member mounts 360, 362.

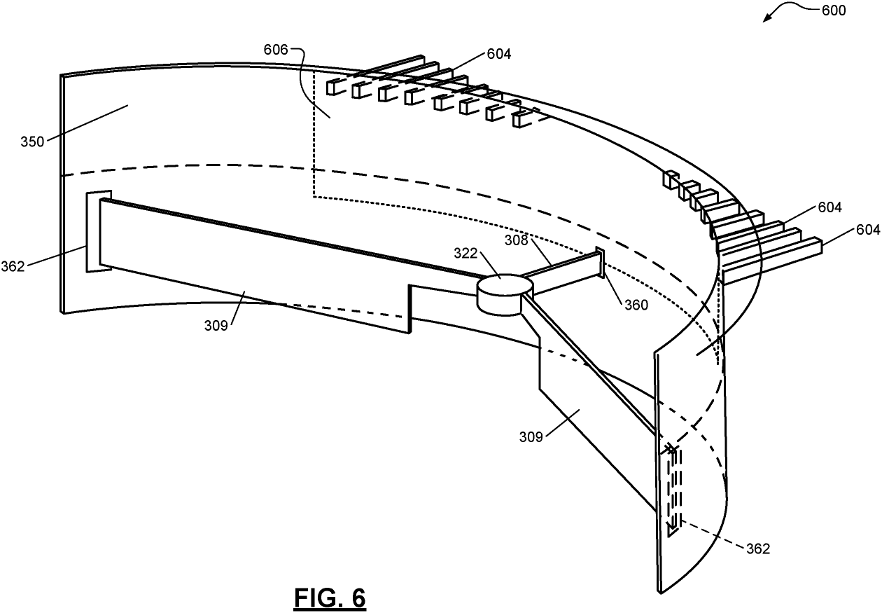

FIG. 6 shows another substrate transfer door assembly 600 that is similar to the substrate transfer door assembly 500 of FIG. 5, but does not include a fin and includes radiating posts 604. The radiating posts 604 extend from a back side of a substrate transfer door 606 and increase surface area of the substrate transfer door 606 for radiating heat. The radiating posts 604 may be referred to as radiating elements and may be rectangularly-shaped as shown. The radiating posts 604 may be shaped differently than shown. For example, in one embodiment, the radiating posts 604 are round tubular-shaped posts. The substrate transfer door 606 is attached to and/or integrally formed with the extension members 306, 307. The substrate transfer door assembly 600 includes the support members 308, 309, central coupler 322 and support member mounts 360, 362.

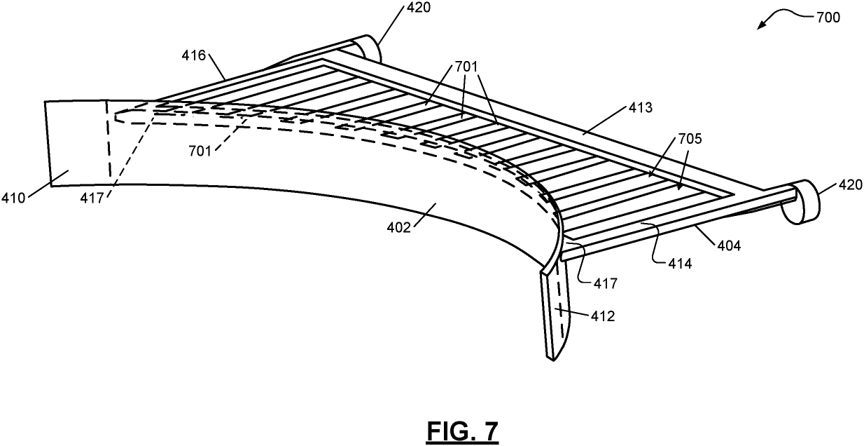

FIG. 7 shows another substrate transfer door assembly 700 that includes framed radiating elements 701 that extend radially away from a substrate transfer door 402. The frame 404 surrounds and supports the radiating elements 701. Air gaps 705 exist between the radiating elements 701. The radiating elements 701 may be shaped differently than shown and provide a different radiating heat pattern than provided by the shown radiating elements 701. Although a particular number of radiating elements are shown, a different number of radiating elements may be included. The substrate transfer door (or central portion) 402 is attached to and/or integrally formed with side extension members 410, 412.

The frame 404 includes the first lateral member 413 and side members 414, 416, which are attached to a back side of the substrate transfer door 402. The frame 404 may include a second lateral member 417 that extends along the back side of the substrate transfer door 402. The side members 414, 416 extend radially from the substrate transfer door 402 (or the second lateral member 417 if included) to the first lateral member 413. The substrate transfer door 402 (and/or the second lateral member 417 if included) and the members 413, 414, 416 are connected to and extend along peripheral edges of the radiating elements 701. The radiating elements 701 increase surface area of the substrate transfer door assembly 400 to cool the substrate transfer door 402. The side members 414, 416 are connected to round bosses (or lifting couplers) 420, which may be connected to an actuator (similar to the actuator 138 of FIG. 1) that moves the substrate transfer door assembly 700 in a vertical and/or horizontal direction to cover and uncover an opening of a processing chamber. In one embodiment, the actuator includes one or more valves and the lifting couplers 420 are connected directly or indirectly to the one or more valves. The radiating elements 701 may be formed of aluminum. In one embodiment, the radiating elements 701 are formed of anodized aluminum, such as black anodized aluminum.

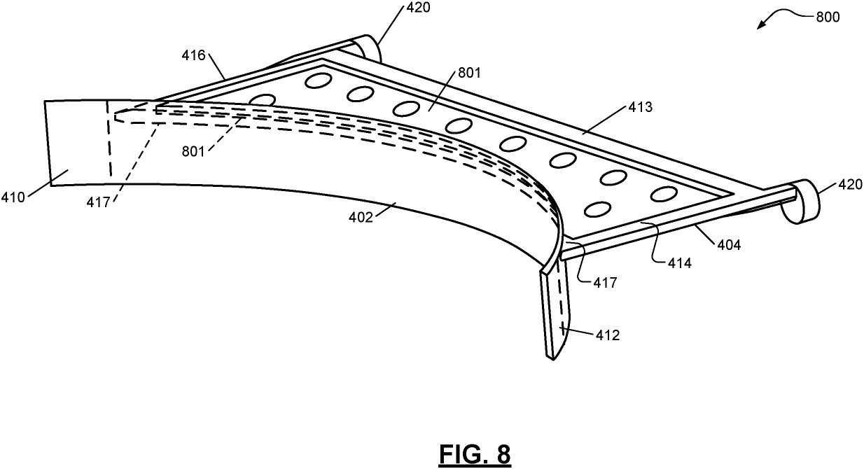

FIG. 8 shows a substrate transfer door assembly 800 with a framed perforated web 801. The web 801 may have various patterns of perforations. The perforations may have different shapes and sizes to provide different heat radiating patterns. In the example shown, the perforations are holes 803. Although a particular number of holes are shown having a particular size, a different number of holes of different sizes may be included. The substrate transfer door assembly 800 further includes the substrate transfer door 402 and the frame 404. The substrate transfer door (or central portion) 402 is attached to and/or integrally formed with side extension members 410, 412.

The frame 404 includes the first lateral member 413 and side members 414, 416, which are attached to a back side of the substrate transfer door 402. The frame 404 may include the second lateral member 417 that extends along the back side of the substrate transfer door 402. The side members 414, 416 extend radially from the substrate transfer door 402 (or the second lateral member 417 if included) to the first lateral member 413. The substrate transfer door 402 (and/or the second lateral member 417 if included) and the members 413, 414, 416 are connected to and extend along a perimeter of the web 801. The web 801 increases surface area of the substrate transfer door assembly 400 to cool the substrate transfer door 402. The side members 414, 416 are connected to round bosses (or lifting couplers) 420, which may be connected to an actuator (similar to actuator 138 of FIG. 1) that moves the substrate transfer door assembly 800 in a vertical and/or horizontal direction to cover and uncover an opening of a processing chamber. In one embodiment, the actuator includes one or more valves and the lifting couplers 420 are connected directly or indirectly to the one or more valves. The web 801 may be formed of aluminum. In one embodiment, the web 801 is formed of anodized aluminum, such as black anodized aluminum.

The above provided examples include heat radiating structures that extend from central portions and/or main bodies of substrate transfer door assemblies to regions where the radiating structures are surrounded by material (e.g., material of chamber walls). Examples of the heat radiating structures include the above-described fins, webs, extension members, support members, etc. The surrounding material is at lower temperatures than the heat radiating structures. As an example, the temperatures of the surrounding material may be at more than 40° C. less than the temperatures of the radiating structures. These temperature differences in, for example, applications where temperatures are 0-300° C., leads to most of the radiating heat being transferred away from the central portions and/or main bodies of the substrate transfer door assemblies. Thermal conduction occurs from the portions of the heat transfer doors on which heat impinges to the outermost ends of at least some of the radiating structures such that the radiating structures are at temperatures more than 40° C. above the surrounding material. This ensures the radiating structures, which are more than 40° C. above the surrounding material, are effective radiators of thermal energy.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from multiple fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate transfer door assembly comprising:
a body comprising a central portion, wherein at least the central portion of the body operates as a substrate transfer door and covers at least one of an opening of a liner or an opening of a chamber wall of a substrate processing chamber;
one or more radiating elements radiating heat away from the body;
a member extending from the body; and
at least one lifting coupler connected to the member and movable in a vertical direction between an open position and a closed position to cover the at least one of the opening of the liner or the opening of the chamber wall with the central portion of the body.

2. The substrate transfer door assembly of claim 1, wherein the one or more radiating elements comprise a bottom extension member that extends down from the body.

3. The substrate transfer door assembly of claim 1, wherein the one or more radiating elements comprise side extension members extending in an azimuthal direction away from the body.

4. The substrate transfer door assembly of claim 1, wherein the one or more radiating elements comprise a fin extending radially from the body.

5. The substrate transfer door assembly of claim 4, further comprising one or more support members extending from and supporting the fin.

6. The substrate transfer door assembly of claim 1, further comprising:
a frame connected to and extending radially from the body; and
a web held by the frame, wherein
the frame includes the member, and
the one or more radiating elements include the web.

7. The substrate transfer door assembly of claim 6, wherein:
the member is a first member;
the frame includes a plurality of members including the first member; and
the web extends between and is connected to each of the plurality of members.

8. The substrate transfer door assembly of claim 6, wherein the one or more radiating elements extend radially away from the body and toward the member.

9. The substrate transfer door assembly of claim 1, wherein the one or more radiating elements comprise a plurality of radiating elements extending radially away from the body.

10. The substrate transfer door assembly of claim 1, further comprising at least one support member extending radially from and structurally supporting the body.

11. The substrate transfer door assembly of claim 10, wherein the at least one support member counterbalances weight of at least a portion of the one or more radiating elements.

12. The substrate transfer door assembly of claim 1, further comprising a plurality of support members connected to the body and to the lifting coupler.

13. The substrate transfer door assembly of claim 12, wherein the plurality of support members at least one of radiate heat away from the body or counterbalance weight of at least a portion of the one or more radiating elements.

14. The substrate transfer door assembly of claim 1, wherein the body covers the opening of the liner and the opening of the chamber wall.

15. The substrate transfer door assembly of claim 1, further comprising a protective coating on at least a portion of an inner side of the body, wherein a portion of the coating faces the at least one of the opening in the liner or the opening in the chamber wall.

16. The substrate transfer door assembly of claim 15, wherein the protective coating faces at least one of an interior of the substrate processing chamber or the opening in the liner.

17. The substrate transfer door assembly of claim 16, wherein:
the body comprises aluminum; and
the protective coating comprises at least one of yttrium oxide, aluminum oxide, aluminum hydroxide, yttrium oxyfluoride, zirconium oxide, or yttrium trifluoride.

18. A substrate transfer system comprising:
the substrate transfer door assembly of claim 1,
an actuating element;
an actuator connected to the actuating element; and
a controller controlling the actuator to move the substrate transfer door assembly between an open state and a closed state.

19. The substrate transfer system of claim 18, further comprising a plurality of support members connected to the body and to the lifting coupler,
wherein the lifting coupler is connected to the actuating element.

20. The substrate transfer system of claim 18, wherein the member extends from the body in a direction away from an interior of the substrate processing chamber.

21. The substrate transfer system of claim 18, wherein the one or more radiating elements extend into the opening of the substrate processing chamber.

22. The substrate transfer system of claim 18, wherein the central portion of the body is disposed between the liner and the chamber wall when the substrate transfer door assembly is in the closed state.
